(19) United States
(12) Patent Application Publication
(10) Pub. No.: US 2003/0217810 A1
(43) Pub. Date: Nov. 27, 2003

(54) Baffle device

(75) Inventors: Fu-sheng Chen, Bade City (TW); Chi-Lu Li, Pingtung City (TW); Ching-Ta Chang, Kaohsiung (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: Winbond Electronic Corp., Hsinchu (TW)

(21) Appl. No.: 10/404,380

(22) Filed: Apr. 1, 2003

(30) Foreign Application Priority Data
May 24, 2002 (TW) 901207646

(51) Int. Cl. H01L 21/306; C23C 16/00

(52) U.S. Cl. 156/345.29; 118/715

(57) ABSTRACT

A baffle device applied to a reaction room for isolating a specific matter is provided. The baffle device includes a main body, a first collecting assemble disposed around the main body and having plural first outlets and plural first collecting strips disposed on the plural first outlets for collecting the specific matter, and a second collecting assembly parallel to the first collecting assembly and having plural second outlets and plural second collecting strips disposed on the specific matter, wherein the first collecting strips and the second collecting strips are mutually arranged alternately.

### FIELD OF THE INVENTION

The present invention relates to a baffle device, and more particular to a baffle plate for reducing particle contamination during the IC manufacturing process.

### BACKGROUND OF THE INVENTION

While the development of an integrated circuit manufacturing process enters nanometer manufacturing process, the requirement of manufacturing process becomes more severe and careful. Actually, the reaction temperature, the wafer cooling effect, the chamber pressure, and the particle directly influence the yield of the product for a semiconductor manufacturing apparatus.

Please refer to FIGS. 1 and 2(a)˜(b) respectively showing a cross-sectional diagram of a chamber and a top view of a baffle plate according to the prior art. As shown in FIG. 1, a chamber has a gas inlet 11, an upper electrode 12, a lower electrode 13, a baffle plate 14, a cathode 15, a gate valve 16, and a pump 17, wherein a wafer 18 is placed on the lower electrode 13. The baffle plate 14 surrounds the down-face of the wafer. While the gas flows into the gas inlet 11, the baffle plate 14 can baffle against the particle to stick to the wafer 18. Moreover, the air flow will be drew out through the gate valve 16 by the operation of the pump 17.

Please refer to FIGS. 2(a)˜(b). Because the structure of the conventional baffle plate has openings or collecting strips which is a plane, the cathode 15 cannot prevent the particle sticking to the wafer 18 while the cathode 15 rises or falls. Therefore, the yield of product will be decreased. Furthermore, because the openings of the baffle plates are intercommunicate directly, the air flow is uniform. However, during the reaction of the reaction room the adjustment of the pressure or the change of the pumping rate will cause the disturbance flow so as to decrease the uniformity of the inner pressure of the reaction room and the stability. Therefore, the uniformity of reaction will be affected.

It is therefore attempted by the applicant to deal with the above situation encountered with the prior art.

### SUMMARY OF THE INVENTION

It is therefore an object of the present invention to propose a baffle device applied to a chamber for isolating a specific matter, which includes a main body, a first collecting assembly disposed around the main body and having plural first outlets and plural first collecting strips disposed on the plural first outlets for collecting the specific matter, and a second collecting assembly parallel to the first collecting assembly and having plural second outlets and plural second collecting strips disposed on the plural second outlets for collecting the specific matter, wherein the first collecting strips and the second collecting strips are mutually arranged alternately.

According to an aspect of the present invention, the specified matter is a particle.

Preferably, each of said collecting strips further includes two inner curved parts.

Preferably, the specific matter can reflow from the plural first outlets and the second outlets.

It is therefore an object of the present invention to propose a baffle device applied to a chamber for isolating a specific matter including a main body, a first collecting assembly disposed around the body and having plural first outlets and plural first collecting strips disposed on the plural first outlets for collecting the specific matter.

Preferably, the specific matter is a particle.

Preferably, each of the collecting strips further comprises two inner curved parts.

Preferably, the specific matter can reflow from the plural first outlets and the second outlets.

The present invention may best be understood through the following description with reference to the accompanying drawings, in which:

### BRIEF DESCRIPTION OF THE DRAWINGS

FIG. 1 illustrates a cross-sectional diagram of a chamber according to the prior art;

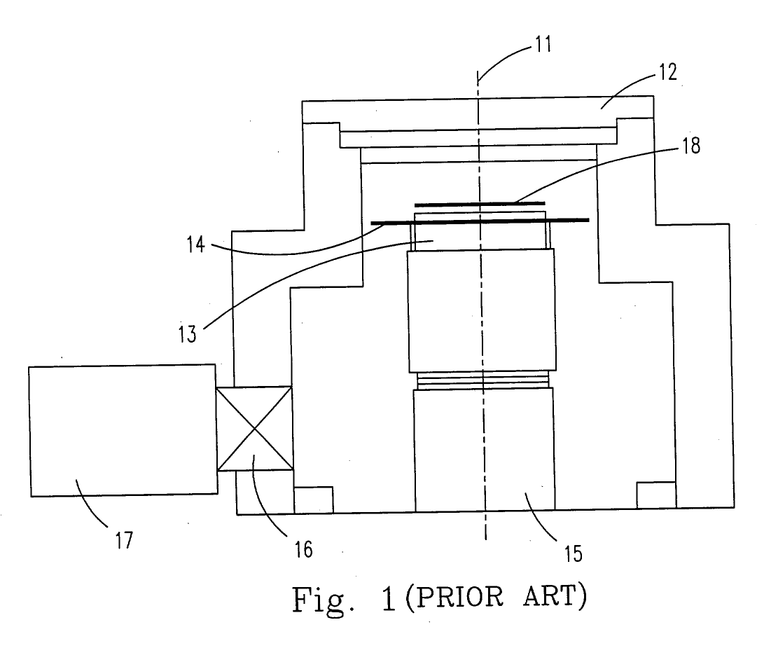

FIGS. 2(a)˜(b) is a top view of a baffle plate according to the prior art;

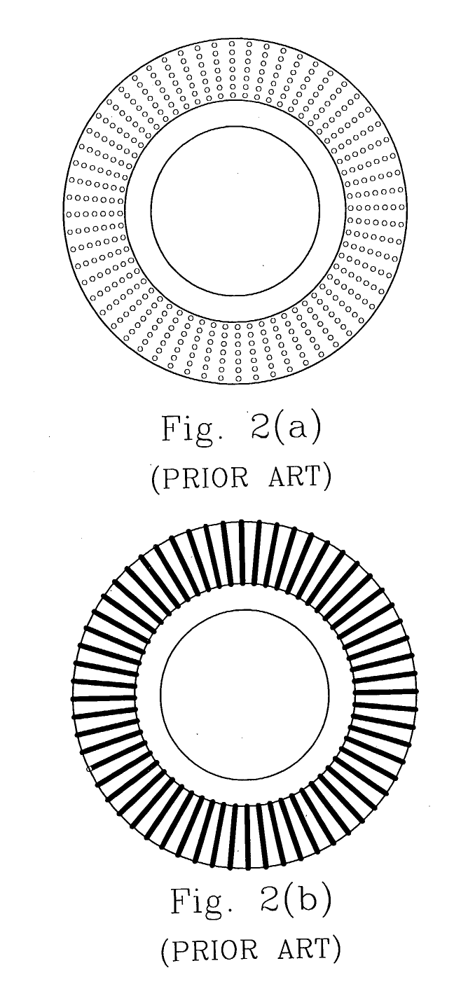

FIG. 3 is a cross-sectional diagram of a double-plate chamber according to a preferred embodiment of the present invention;

FIG. 4 is a top view of a baffle plate according to a preferred embodiment of the present invention; and

FIG. 5(a)˜(b) is a cross-sectional diagram of the baffle plate according to a preferred embodiment of the present invention.

### DETAILED DESCRIPTION OF THE PREFERRED EMBODIMENT

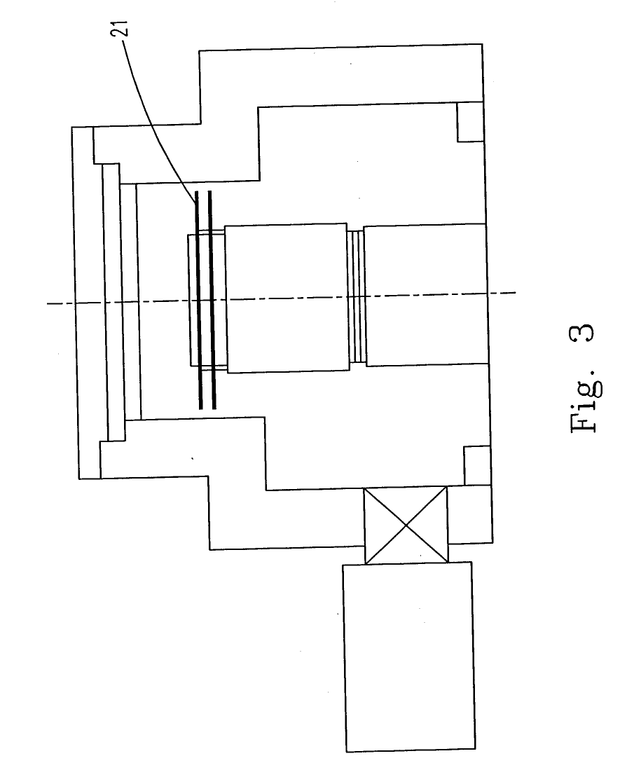

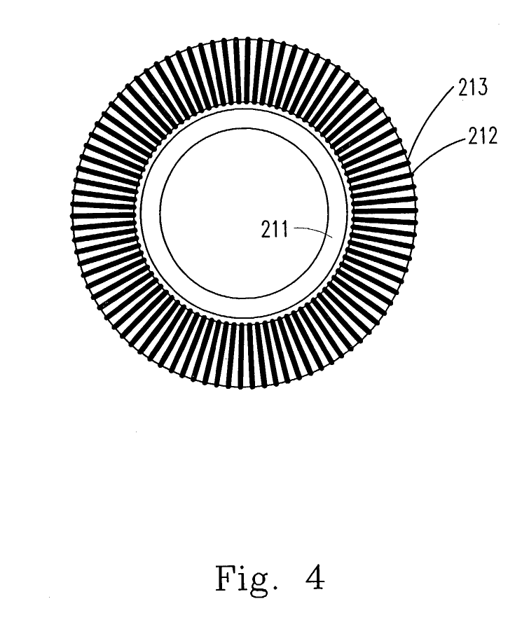

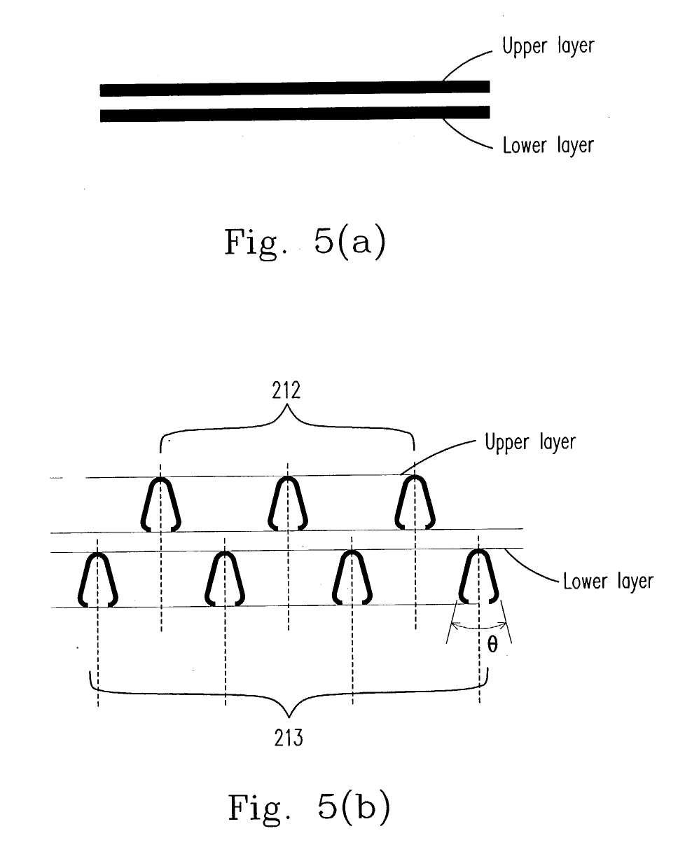

Please refer to FIG. 3 and FIG. 4, which show a cross-sectional diagram of a double-plate chamber according to a preferred embodiment of the present invention and a top view of a baffle plate according to a preferred embodiment of the present invention respectively. As shown in FIG. 3, the position of the double-baffle plate 21 is the same with a conventional baffle plate of a chamber. However, as shown in FIG. 4, the structure of the double-plate baffle is tighter than that of the conventional baffle plate because of the double-plate design. Also, referring to FIGS. 5(a)˜(b), the shape of the composing elements of the double-baffle plate is more special than the conventional baffle plate. This double-plate baffle includes a main body 211, a first collecting strips assembly 212 and a second collecting strips assembly 213, wherein the first collecting strips assembly 212 and the second collecting strips assembly 213 are disposed along the radial lines of the surface of the main body. The first collecting strips assembly is parallel with the second collecting strips assembly (as shown in FIG. 5(a)). Additionally, the second collecting strips (hereinafter, called a dust-collecting slice) of the second collecting strips assembly 213 relative to the first collecting strips of the first collecting strips assembly 212 are arranged mutually and alternately as shown in FIG. 5(b).

The structure of the collecting strips of the first collecting strips assembly 212 and the second collecting strips assembly 213 are triangular shapes so that the particle is easy to fall down and hard to rise. There is an opening disposed at the bottom of the triangular shape and two sides of the triangular shape are curved inside. Therefore, the curved portion of the triangular shape can receive and carry on the particle. Moreover, the angle of the tip of the triangular shape is optimally designed about 5˜20 degrees.

The baffle device is composed of at least one layer of the baffle plate. Hence, the number of the layers of the baffle plate cannot be restricted by a maximum number. The number of the layers of the baffle plate should be added to the real demand, which depends on the manufacturing cost. Therefore, the present invention has the advantage of easily changing the number of the layers of the baffle plate.

According to an aspect of the present invention, the present invention improves the conventional collecting strips assembly baffle plate by employing a triangular

While the invention has been described in terms of what are presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A baffle device applied to a reaction room for isolating a specific matter, comprising:
a main body;
a first collecting assembly disposed around said main body and having plural first outlets and plural first collecting strips disposed on said plural first outlets for collecting said specific matter; and
a second collecting assembly parallel to said first collecting assembly and having plural second outlets and plural second collecting strips disposed on said specific matter, wherein said first collecting strips and said second collecting strips are mutually arranged alternately.

2. The baffle device according to claim 1, wherein said specific matter is a particle.

3. The baffle device according to claim 1, wherein said each of said collecting strips further comprises two inner curved parts.

4. The baffle device according to claim 1, wherein said specific matter can reflow from said plural first outlets and said second outlets.

5. The baffle device applied to a chamber for isolating a specific matter, comprising:
a main body;
a first collecting assembly disposed around said body and having plural first outlets and plural first collecting strips disposed on said plural first outlets for collecting said specific matter.

6. The baffle device according to claim 5, wherein said specific matter is a particle.

7. The baffle device according to claim 5, wherein each of said collecting strips further comprises two inner curved parts.

8. The baffle device according to claim 5, wherein said specific matter can reflow from said plural first outlets and said second outlets.
